(19) United States
(12) Patent Application Publication
(10) Pub. No.: US 2011/0102024 A1
(43) Pub. Date: May 5, 2011

(54) DATA OUTPUT CIRCUIT

(75) Inventors: Seong Seop LEE, Gyeonggi-do (KR); Saeng Hwan KIM, Gyeonggi-do (KR)

(73) Assignee: HYNIX SEMICONDUCTOR INC., Gyeonggi-do (KR)

(21) Appl. No.: 12/825,780

(22) Filed: Jun. 29, 2010

(30) Foreign Application Priority Data
Oct. 30, 2009 (KR) 10-2009-0104365

(51) Int. Cl. H03K 3/00

(52) U.S. Cl. 327/108

(57) ABSTRACT

The data output circuit includes a pull-up signal generator, a pull-down signal generator and a driver. The pull-up signal generator is configured to generate a pull-up signal that is driven to a first level state when a pre-pull-up signal is activated and driven to a second level state after a first delay period. The pull-down signal generator is configured to generate a pull-down signal that is driven to a third level state when a pre-pull-down signal is activated and driven to a fourth level state after a second delay period. The driver is configured to drive output data in response to receiving either the pull-up signal and the pull-down signal.

### CROSS-REFERENCE TO RELATED APPLICATIONS

The present application claims priority under 35 U.S.C 119(a) to Korean Application No. 10-2009-104365, filed on Oct. 30, 2009, in the Korean Intellectual Property Office, which is incorporated by reference in its entirety as set forth in full.

### BACKGROUND

The present invention relate to a data output circuit.

Generally mobile-specific double data rate dynamic random access memories (mobile DDR DRAMs) or mobile DDR2 DRAMs do not to use terminations in view of input interface, because these memories are required to be operable at relatively low power levels required by the portable environment. Instead of this, for the purpose of assuring stable signal integrity against impedance of signal lines along with package substrates, it is necessary to substantially achieve slew rates suitable for impedance circumstances of semiconductor memories.

FIG. 1 shows a general data output circuit.

As shown in FIG. 1, the data output circuit is formed of an inverter IV10, an inverter IV11, a PMOS transistor P10 and an NMOS transistor N10. The inverter IV10 generates a first pull-up signal PUB1 by inversely buffering a pre-pull-up signal PU0 that is activated to a high level state when data is conditioned at a high level state. The inverter IV11 generates a first pull-down signal PD1 by inversely buffering a pre-pull-down signal PDB0 that is activated to a low level state when data is conditioned at a low level state. The PMOS transistor P10 raises a voltage level of the first output data DOUT1 in response to the first pull-up signal PUB1. The NMOS transistor N10 decreases a voltage level of the first output data DOUT1 in response to the first pull-down signal PD1.

With this configuration of the data output circuit, it is possible to adjust a slew rate in some degree by modifying the sizes of the inverters IV10 and IV11, but there is a limit to substantially providing an operative slew rate suitable for a given impedance circumstance of a semiconductor memory. While another data output circuit employs a resistor and a capacitor in order to control a slew rate, those passive elements of resistor and capacitor cause the data output circuit to be unacceptably enlarged with regards to layout size.

### SUMMARY

Accordingly, embodiments of the present invention are directed to a data output circuit capable of easily adjusting a slew rate by means of the characteristics of transmission gates.

In an embodiment, a data output circuit may include: a pull-up signal generator configured to generate a pull-up signal that is driven to a first level state when a pre-pull-up signal is activated and driven to a second level state after a first delay period; a pull-down signal generator configured to generate a pull-down signal that is driven to a third level state when a pre-pull-down signal is activated and driven to a fourth level state after a second delay period; and a driver configured to drive output data in response to receiving the pull-up signal and the pull-down signal.

In another embodiment, a data output circuit may include: a pull-up signal generator configured to generate a pull-up signal that is driven to a first level state when a pre-pull-up signal is activated, driven to a second level state after a first delay period, and driven to a third level state after a second delay period; a pull-down signal generator configured to generate a pull-down signal that is driven to a fourth level state when a pre-pull-down signal is activated, driven to a fifth level state after a third delay period, and driven to a sixth level state after a fourth delay period; and a driver configured to drive output data in response to receiving the pull-up signal and the pull-down signal.

A further understanding of the nature and advantages of the present invention herein may be realized by reference to the remaining portions of the specification and the attached drawings.

### BRIEF DESCRIPTION OF THE DRAWINGS

The above and other aspects, features and other advantages will be more clearly understood from the following detailed description taken in conjunction with the accompanying drawings, in which:

FIG. 1 shows a general data output circuit;

FIG. 2 illustrates a data output circuit according to an embodiment of the present invention;

FIG. 3 illustrates an operation of the data output circuit shown in FIG. 2; and

FIG. 4 illustrates a data output circuit according to another embodiment of the present invention.

### DESCRIPTION OF EMBODIMENTS

Hereinafter, various exemplary embodiments will now be described more fully with reference to the accompanying drawings in which some exemplary embodiments are shown. However, specific structural and functional details disclosed herein are merely representative for purposes of describing exemplary embodiments of the present invention. Like numbers refer to like elements throughout the description of the drawings.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Further, it will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the invention. As used herein, the term “and/or” includes any and all combinations of one or more of the associated listed items. Also will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In order to more specifically describe exemplary embodiments, various aspects will be hereinafter described in detail with reference to the attached drawings.

FIG. 2 illustrates a data output circuit according to an embodiment of the present invention.

Referring to FIG. 2, the data output circuit according to this embodiment may comprise a first pull-up signal generator 20, a first pull-down signal generator 21 and a first driver 22.

The first pull-up signal generator 20 is exemplary comprised of an inverter IV20, a first delay circuit 200, an inverter IV21, a transmission gate T20 and a PMOS transistor P20. The inverter IV20 functions as a buffer configured to inversely buffer a pre-pull-up signal PU0. The first delay circuit 200 is configured to delay the pre-pull-up signal PU0 by a first delay period. The inverter IV21 functions as a buffer configured to inversely buffer the pre-pull-up signal PU0. The transmission gate T20 transfers an output signal of the inverter IV20 as a second pull-up signal PUB2 in response to output signals of the first delay circuit 200 and the inverter IV21. The PMOS transistor P20 functions as a pull-up element configured to raise a voltage level of the second pull-up signal PUB2 to an external voltage VDD in response to the pre-pull-up signal PU0. The pre-pull-up signal PU0 is activated in a high level state when input data is laid on a high level state, but inactivated in a low level state when input data is laid on a low level state. The transmission gate T20 may be formed of a PMOS transistor and an NMOS transistor.

The first pull-down signal generator 21 is exemplary composed of an inverter IV22, a second delay circuit 210, an inverter IV22, a transmission gate T21 and an NMOS transistor N20. The inverter IV21 functions as a buffer configured to inversely buffer a pre-pull-down signal PDB0. The second delay circuit 210 is configured to delay the pre-pull-down signal PDB0 by a second delay period. The inverter IV22 functions as a buffer configured to inversely buffer the pre-pull-down signal PDB0. The transmission gate T21 transfers an output signal of the inverter IV22 as a second pull-down signal PD2 in response to output signals of the second delay circuit 210 and the inverter IV23. The NMOS transistor N20 functions as a pull-down element configured to decrease a voltage level of the second pull-down signal PD2 to the ground voltage VSS in response to the pre-pull-down signal PDB0. The pre-pull-down signal PDB0 is activated in a high level state when input data is at a high level state, but inactivated in a low level state when input data is at a low level state.

The first driver 22 may be formed of a PMOS transistor P21 and an NMOS transistor N21. The PMOS transistor P21 functions as a pull-up element configured to raise a voltage level of the second output data DOUT2 to the external voltage VDD in response to the second pull-up signal PUB2. The NMOS transistor N21 functions as a pull-down element configured to decrease a voltage level of the second output data DOUT2 to the ground voltage VSS in response to the second pull-down signal PD2.

When the PMOS and NMOS transistors (not shown) of the transmission gate T20 are all turned on, an input signal of the transmission gate T20 is fully transferred to the output of the transmission gate T20. When the PMOS transistor of the transmission gate T20 is only turned on, an input signal of the transmission gate T20 is transferred to the output of the transmission gate T20 at a voltage level of VDD-Vth1. When the NMOS transistor of the transmission gate T20 is only turned on, an input signal of the transmission gate T20 is transferred to the output of the transmission gate T20 at a voltage level of Vth2. Here, Vth1 is the threshold voltage of the PMOS transistor (not shown) of the transmission gate T20. Vth2 is the threshold voltage of the NMOS transistor (not shown) of the transmission gate T20. The transmission gate T21 may be same as the transmission gate T20.

With this configuration of the data output circuit, when there is no input of data, the pre-pull-up signal PU0 is inactivated to a low level state and the pre-pull-down signal PDB0 is inactivated to a high level state. Then, the PMOS transistor P20 is turned on to raise a voltage level of the second pull-up signal PUB2 to the external voltage VDD and the NMOS transistor N20 is turned on to decrease a voltage level of the second pull-down signal PD2 to the ground voltage VSS. In this condition that the second pull-up signal PUB2 is driven up to the external voltage VDD and the second pull-down signal PD2 is driven down to the ground voltage VSS, the output data DOUT2 is substantially maintained at a high-Z state because the PMOS and NMOS transistors P21 and N21 of the first driver 22 are all turned off which interrupts the second drive current IP2.

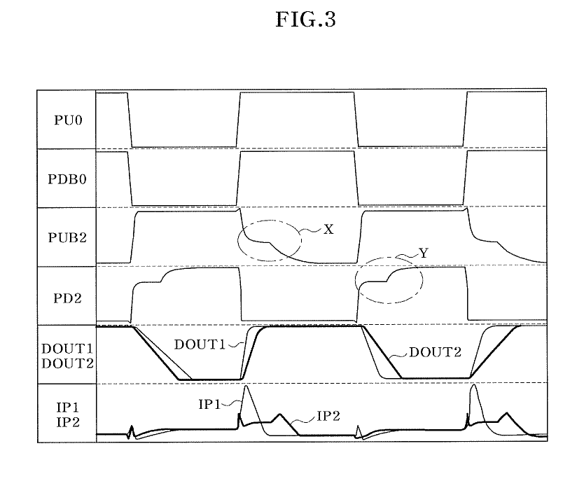

Now an operation of the data output circuit with data input will be described with reference to FIG. 3, while divisionally considering two cases: one case is when data is input having a high level state; and the other case is when data is input having a low level state.

First, the case when data is input having a high level state is as follows.

When data is input at a high level state, the pre-pull-down signal PDB0 is inactivated to a high level state. Then, the transmission gate T21 is turned off and the NMOS transistor N20 is turned on. Accordingly, the second pull-down signal PD2 goes to the ground voltage VSS and the NMOS transistor N21 of the first driver 22 is turned off.

Since the pre-pull-up signal PU0 is activated into a high level state when data is input at a high level state, the PMOS transistor P20 is turned off and only the PMOS transistor (not shown) of the transmission gate T20 is turned on. When only the PMOS transistor (not shown) of the transmission gate T20 is turned on, then the second pull-up signal PUB2 is charged to VDD-Vth1. Here, Vth1 is the threshold voltage of the PMOS transistor of the transmission gate T20. After the first delay period of the first delay circuit 200, since the pre-pull-up signal PU0 has been activated to a high level state, then the NMOS transistor of the transmission gate T20 is also turned on. Then, the transmission gate T20 transfers an output signal of the inverter IV20 as the second pull-up signal PUB2. The second pull-up signal PUB2 is driven to the ground voltage VSS to make the PMOS transistor P21 of the first driver 22 conductive. Thus, a voltage level of the second output data DOUT2 is pulled up to the external voltage VDD.

Next, the case when data is input at a low level state is as follows.

When data is input at a low level state, the pre-pull-up signal PU0 is inactivated to a low level state. Then, the transmission gate T20 is turned off and the PMOS transistor P20 is turned on. Accordingly, the second pull-up signal PUB2 goes to the external voltage VDD and the PMOS transistor P21 of the first driver 22 is turned off.

Since the pre-pull-down signal PDB0 is activated to a low level state when data is input in a low level state, the NMOS transistor N20 is turned off and only the NMOS transistor of the transmission gate T21 is turned on. When only the NMOS transistor of the transmission gate T21 is turned on, then the second pull-down signal PD2 goes to Vth2. Here, Vth2 is the threshold voltage of the NMOS transistor (not shown) of the transmission gate T21. After the second delay period of the second delay circuit 210, since the pre-pull-down signal PD0 has been activated to a high level state, then the PMOS transistor of the transmission gate T21 is also turned on. Then, the transmission gate T21 transfers an output signal of the inverter IV22 as the second pull-down signal PD2. The second pull-down signal PD2 is driven on the external voltage VDD to make the NMOS transistor N21 of the first driver 22 conductive. Thus, a voltage level of the second output data DOUT2 is pulled down to the ground voltage VSS.

As aforementioned, the data output circuit according to this embodiment operates to control a slew rate of the second output data DOUT2 by means of the configuration with the first delay circuit 200, the transmission gate T20, the second delay circuit 210 and the transmission gate T21. In summary, the second pull-up signal PUB2 is driven in the sequence of voltage levels VDD, VDD-Vth1 and VSS when data is input at a high level state and the second pull-down signal PD2 is driven in the sequence of voltage levels VSS, Vth2 and VDD when data is input at a low level state. As a result, the second output data DOUT2 is improved in slew rate.

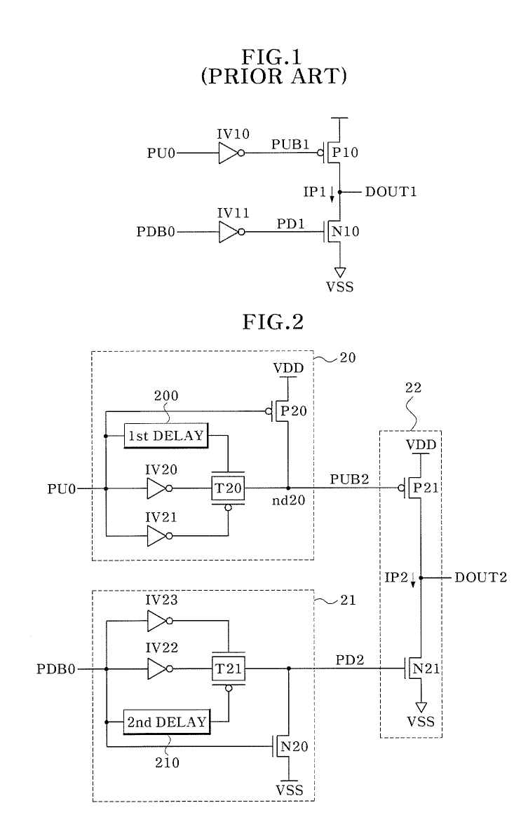

Now referring to FIG. 3, it can be seen that the voltage level of the second pull-up signal PUB2 is stepped down along the waveform X and the voltage level of the second pull-down signal PD2 is stepped up along the waveform Y. As a result, the second output data DOUT2, which is driven by the second pull-up and pull-down signals PUB2 and PD2 whose voltage levels are stepping up and down respectively, is lower than the first output data DOUT1, which is driven by the data output circuit shown in FIG. 1, in pull-up/down driving rate. That is, the second output data DOUT2 according to this embodiment of the present invention is smaller than the first output data DOUT1 of the former data output circuit shown in FIG. 1. Therefore, a peak value of the second drive current IP2 of the first driver 22 included in the data output circuit according to this embodiment is smaller than that of the first drive current IP1 of the data output circuit shown in FIG. 1.

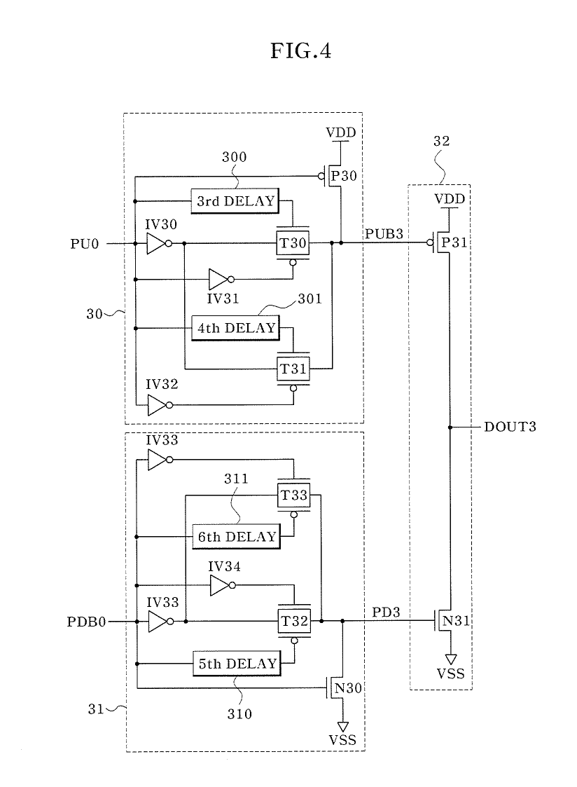

FIG. 4 illustrates a data output circuit according to another embodiment of the present invention. Referring to FIG. 4, the data output circuit may comprise a second pull-up signal generator 30, a second pull-down signal generator 31 and a second driver 32.

The second pull-up signal generator 30 is exemplarily comprised of an inverter IV30, a third delay circuit 300, an inverter IV31, a transmission gate T30, a fourth delay circuit 301, an inverter IV32, a transmission gate T31 and a PMOS transistor P30. The inverter IV30 functions as a buffer configured to inversely buffer a pre-pull-up signal PU0. The third delay circuit 300 is configured to delay the pre-pull-up signal PU0 by a third delay period. The inverter IV31 functions as a buffer configured to inversely buffer the pre-pull-up signal PU0. The transmission gate T30 transfers an output signal of the inverter IV30 as a third pull-up signal PUB3 in response to output signals of the third delay circuit 300 and the inverter IV31. The fourth delay circuit 301 operates to delay the pre-pull-up signal PU0 by a fourth delay period. The inverter IV32 functions as a buffer configured to inversely buffer the pre-pull-up signal PU0. The transmission gate T31 transfers an output signal of the inverter IV30 as the third pull-up signal PUB3 in response to output signals of the fourth delay circuit 301 and the inverter IV32. The PMOS transistor P30 functions as a pull-up element configured to raise a voltage level of the third pull-up signal PUB3 to the external voltage VDD in response to the pre-pull-up signal PU0.

The second pull-down signal generator 31 is exemplarily comprised of an inverter IV33, a fifth delay circuit 310, an inverter IV34, a transmission gate T32, a sixth delay circuit 311, an inverter IV35, a transmission gate T33 and an NMOS transistor N30. The inverter IV33 functions as a buffer configured to inversely buffer a pre-pull-down signal PDB0. The fifth delay circuit 310 operates to delay the pre-pull-down signal PDB0 by a fifth delay period. The inverter IV34 functions as a buffer configured to inversely buffer the pre-pull-down signal PDB0. The transmission gate T32 transfers an output signal of the inverter IV33 as a third pull-down signal PD3 in response to output signals of the fifth delay circuit 310 and the inverter IV34. The sixth delay circuit 311 operates to delay the pre-pull-down signal PDB0 by a sixth delay period. The inverter IV35 functions as a buffer configured to inversely buffer the pre-pull-down signal PDB0. The transmission gate T33 transfers an output signal of the inverter IV33 as the third pull-down signal PD3 in response to output signals of the sixth delay circuit 311 and the inverter IV35. The NMOS transistor N30 functions as a pull-down element configured to decrease a voltage level of the third pull-down signal PD3 to the ground voltage VSS in response to the pre-pull-down signal PDB0.

The second driver 32 is exemplarily comprised of a PMOS transistor P31 and an NMOS transistor N31. The PMOS transistor P31 functions as a pull-up element configured to raise a voltage level of the third output data DOUT3 to the external voltage VDD in response to the third pull-up signal PUB3. The NMOS transistor N31 functions as a pull-down element configured to decrease a voltage level of the third output data DOUT3 to the ground voltage VSS in response to the third pull-up signal PUB3.

The structural feature of the data output circuit shown in FIG. 4 is characterized in the configuration with the second pull-up signal generator 30, which includes the third delay circuit 300 and the fourth delay circuits 301, and the second pull-down signal generator 31 including the fifth delay circuit 310 and the sixth delay circuits 311.

When data is input in a high level state, the second pull-up signal generator 30 drives the third pull-up signal PUB3 in the sequence of VDD, VDD-Vth3, VDD-Vth4 and VDD. Here, Vth3 is the threshold voltage of the PMOS transistor (not shown) included in the transmission gate T30. Vth4 is the threshold voltage of the PMOS transistor (not shown) included in the transmission gate T31.

When data is input in a low level state, the second pull-down signal generator 31 drives the third pull-down signal PD3 in the sequence of VSS, Vth5, Vth5+Vth6 and VDD. Here, Vth5 is the threshold voltage of the NMOS transistor (not shown) included in the transmission gate T32. Vth6 is the threshold voltage of the NMOS transistor (not shown) included in the transmission gate T33.

As described above, the third pull-up signal PUB3 and the third pull-down signal PD3, which are driven stepwise, are helpful to reducing a slew rate of the third output data DOUT3 and lowering a peak value of the drive current flowing through the second driver 32.

The foregoing is illustrative of exemplary embodiments and is not to be construed as limiting thereof. Although a few exemplary embodiments have been described, those skilled in the art will readily appreciate that many modifications are possible in exemplary embodiments without materially departing from the novel teachings and advantages. Accordingly, all such modifications are intended to be included within the scope of this invention as defined in the claims.

What is claimed is:

1. A data output circuit comprising:
a pull-up signal generator configured to generate a pull-up signal that is driven to a first level state when a pre-pull-up signal is activated and the pull-up signal is subsequently driven to a second level state after a first delay period;
a pull-down signal generator configured to generate a pull-down signal that is driven to a third level state when a pre-pull-down signal is activated and the pull-down signal is subsequently driven to a fourth level state after a second delay period; and
a driver configured to drive output data in response to the pull-up signal and the pull-down signal.

2. The data output circuit according to claim 1, wherein the pull-up signal generator comprises:
a first buffer configured to buffer the pre-pull-up signal;
a delay circuit configured to delay the pre-pull-up signal by the first delay period;
a second buffer configured to buffer the pre-pull-up signal; and
a transmission gate configured to transfer an output signal from the first buffer as the pull-up signal in response to output signals of the delay circuit and the second buffer.

3. The data output circuit according to claim 2, wherein the pull-up signal generator further comprises: a pull-up element configured to raise a voltage level of the pull-up signal in response to the pre-pull-up signal.

4. The data output circuit according to claim 1, wherein the pull-down signal generator comprises:
a first buffer configured to buffer the pre-pull-down signal;
a delay circuit configured to delay the pre-pull-down signal by the second delay period;
a second buffer configured to buffer the pre-pull-down signal; and
a transmission gate configured to transfer an output signal from the first buffer as the pull-down signal in response to output signals of the delay circuit and the second buffer.

5. The data output circuit according to claim 4, wherein the pull-down signal generator further comprises: a pull-down element configured to decrease a voltage level of the pull-down signal in response to the pre-pull-down signal.

6. A data output circuit comprising:
a pull-up signal generator configured to generate a pull-up signal that is driven to a first level state when a pre-pull-up signal is activated, the pull-up signal driven to a second level state after a first delay period, and the pull-up signal driven to a third level state after a second delay period;
a pull-down signal generator configured to generate a pull-down signal that is driven to a fourth level state when a pre-pull-down signal is activated, the pull-down signal is driven to a fifth level state after a third delay period, and the pull-down signal is driven to a sixth level state after a fourth delay period; and
a driver configured to drive output data in response to the pull-up signal and the pull-down signal.

7. The data output circuit according to claim 6, wherein the pull-up signal generator comprises:
a first buffer configured to buffer the pre-pull-up signal;
a first delay circuit configured to delay the pre-pull-up signal by the first delay period;
a second buffer configured to buffer the pre-pull-up signal;
a first transmission gate configured to transfer an output signal from the first buffer as the pull-up signal in response to output signals from the first delay circuit and the second buffer;
a second delay circuit configured to delay the pre-pull-up signal by the second delay period;
a third buffer configured to buffer the pre-pull-up signal; and
a second transmission gate configured to transfer an output signal from the first buffer as the pull-up signal in response to output signals from the second delay circuit and the third buffer.

8. The data output circuit according to claim 7, wherein the pull-up signal generator further comprises: a pull-up element configured to raise a voltage level of the pull-up signal in response to the pre-pull-up signal.

9. The data output circuit according to claim 6, wherein the pull-down signal generator comprises:
a first buffer configured to buffer the pre-pull-down signal;
a first delay circuit configured to delay the pre-pull-down signal by the first delay period;
a second buffer configured to buffer the pre-pull-down signal;
a first transmission gate configured to transfer an output signal from the first buffer as the pull-down signal in response to output signals of the first delay circuit and the second buffer;
a second delay circuit configured to delay the pre-pull-down signal by the second delay period;
a third buffer configured to buffer the pre-pull-down signal; and
a second transmission gate configured to transfer an output signal from the first buffer as the pull-down signal in response to output signals from the second delay circuit and the third buffer.

10. The data output circuit according to claim 9, wherein the pull-down signal generator further comprises: a pull-down element configured to decrease a voltage level of the pull-down signal in response to the pre-pull-down signal.
